(19) United States
(12) Patent Application Publication
(10) Pub. No.: US 2015/0124360 A1
(43) Pub. Date: May 7, 2015

(54) INVERTER-EMBEDDED SILICON CONTROLLED RECTIFIER

(71) Applicants: Nathan D. Jack, Forest Grove, OR (US); Steven S. Poon, Portland, OR (US)

(72) Inventors: Nathan D. Jack, Forest Grove, OR (US); Steven S. Poon, Portland, OR (US)

(21) Appl. No.: 14/127,959

(22) PCT Filed: Nov. 1, 2013
(86) PCT No.: PCT/US2013/068141

§ 371 Date: Dec. 19, 2013

(51) Int. Cl. H02H 9/04; G06F 1/16; H01L 29/66; H02J 5/00; H01F 38/14

(52) U.S. Cl. CPC H02H 9/04; H02J 5/005; H01F 38/14; H01L 29/66325; G06F 1/16
USPC 361/56; 438/135; 361/679.31; 361/679.21

(57) ABSTRACT

Described is a low power clamp or driver comprising: an inverter; and a silicon controlled rectifier (SCR) embedded in the inverter such that the SCR is part of the inverter. The clamp offers improved conductance per area and lower leakage current compared to the traditional PMOS-based active rail clamps. The clamp or driver combines a trigger circuit with the inverter-embedded SCR for maximum area efficiency. The clamp or driver also results in less stringent requirements for power ramp rates.

### CLAIM OF PRIORITY

This application claims the benefit of priority of International Patent Application No. PCT/US2013/068141 filed Nov. 1, 2013, titled “INVERTER-EMBEDDED SILICON CONTROLLED RECTIFIER,” which is incorporated by reference in its entirety.

### BACKGROUND

It is common practice to use very large MOSFET devices to build electrostatic discharge (ESD) rail clamp protection elements between power and ground. One typical ESD unit is shown in FIG. 1. Here, ESD unit 100 includes a large p-type device MP1, inverters inv1 and inv2, and an RC (resistance-capacitance) timer. The RC timer includes a resistor R and capacitor C coupled in series between power supply Vcc and ground Vss nodes.

During normal operation, capacitor C is charged to Vcc which causes trigger node to be charged to Vcc. A charged up trigger node causes trigger_b node to discharge by inverter inv1. A discharged trigger_b causes inverter inv2 to charge up trigger_d node which causes MP1 to remain off. During an ESD event, MP1 is turned on because trigger node is discharged to ground. MP1 is kept on for the duration of the ESD event. The turn on/off time of MP1 is controlled by the RC time constant.

For ESD unit 100 to operate effectively, MP1 must be sized large enough to carry several amperes of current during an ESD event without entering the breakdown region. This results in the use of several very large clamps that consume a significant portion of total die area. Such MOSFET-based active clamps also require a timer circuit to turn on the clamp during an ESD event and to keep it on until the event is over (typically lasting over 1 microsecond). However, this also means that the clamp can unintentionally turn on during normal power-up of the device if the supply ramping occurs in a short period (e.g., under approx. 1 microsecond). This results in wasted power and unstable operation. The off-state leakage current of MP1 also contributes to static power consumption.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a conventional ESD unit.

FIG. 2 illustrates a high level block diagram of an ESD unit comprising an inverter-embedded silicon controlled rectifier (SCR), according to one embodiment of the disclosure.

FIG. 3 illustrates a circuit of the ESD unit of FIG. 2, according to one embodiment of the disclosure.

FIG. 4 illustrates a top view of a layout of an inverter-embedded SCR, according to one embodiment of the disclosure.

FIG. 5 illustrates a side view of an inverter-embedded SCR, according to one embodiment of the disclosure.

FIG. 6 illustrates a processor with an ESD unit having inverter-embedded SCR, according to one embodiment of the disclosure.

FIG. 7 illustrates a flowchart of forming an inverter-embedded SCR, according to one embodiment of the disclosure.

FIG. 8 illustrates an I/O (i.e., input-output transceiver terminal) with an inverter-embedded SCR, according to one embodiment of the disclosure.

FIG. 9 illustrates a side view of I/O with the inverter-embedded SCR of FIG. 8, according to one embodiment of the disclosure.

FIG. 10 is a smart device or a computer system or an SoC (System-on-Chip) with an inverter-embedded, according to one embodiment of the disclosure.

### DETAILED DESCRIPTION

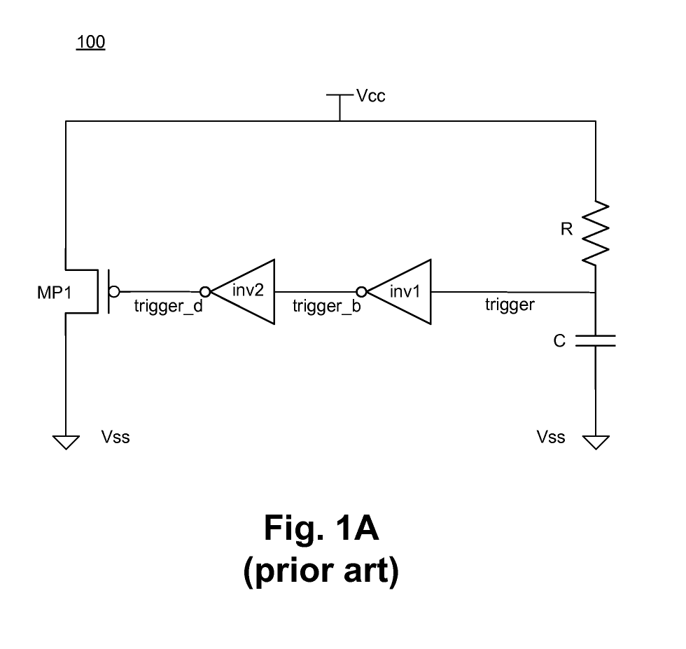

The embodiments describe an inverter-embedded silicon-controlled rectifier (SCR) as a clamp to offer improved conductance per area and lower leakage current compared to the traditional PMOS-based active rail clamp of FIG. 1. The embodiments combine a trigger circuit with the inverter-embedded SCR for maximum area efficiency. The embodiments also result in less stringent requirements for power ramp rates.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct electrical connection between the things that are connected, without any intermediary devices. The term “coupled” means either a direct electrical connection between the things that are connected or an indirect connection through one or more passive or active intermediary devices. The term “circuit” means one or more passive and/or active components that are arranged to cooperate with one another to provide a desired function. The term “signal” means at least one current signal, voltage signal or data/clock signal. The meaning of “a”, “an”, and “the” include plural references. The meaning of “in” includes “in” and “on.”

The term “scaling” generally refers to converting a design (schematic and layout) from one process technology to another process technology. The term “scaling” generally also refers to downsizing layout and devices within the same technology node. The term “scaling” may also refer to adjusting (e.g., slow down) of a signal frequency relative to another parameter, for example, power supply level. The terms “substantially,” “close,” “approximately,” “near,” and “about,” generally refer to being within +/−20% of a target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For purposes of the embodiments, the transistors are metal oxide semiconductor (MOS) transistors, which include drain, source, gate, and bulk terminals. The transistors also include Tri-Gate and FinFET transistors, Gate All Around Cylindrical Transistors or other devices implementing transistor functionality like carbon nano tubes or spintronic devices. Source and drain terminals may be identical terminals and are interchangeably used herein. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., NMOS, NPN BJT, etc.) and the term “MP” indicates a p-type transistor (e.g., PMOS, PNP BJT, etc.).

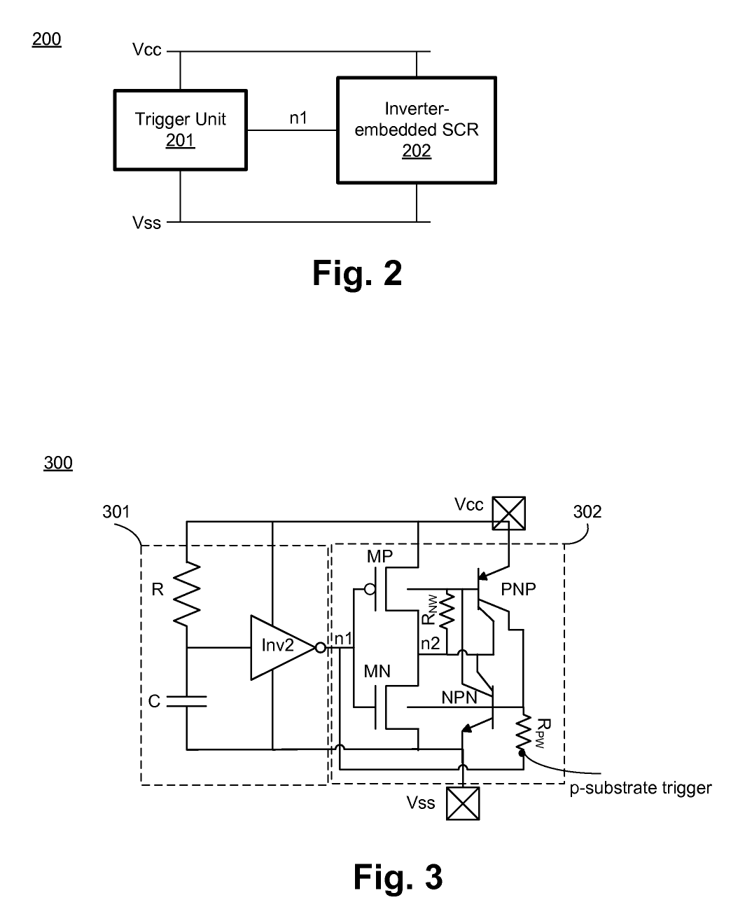

FIG. 2 illustrates a high level block diagram of an ESD unit 200 comprising an inverter-embedded SCR, according to one embodiment of the disclosure. In one embodiment, ESD unit 200 comprises a trigger unit 201 and an inverter-embedded SCR 202. In one embodiment, trigger unit 201 is coupled to inverter-embedded SCR 202 via node n1. ESD unit 200 provides protection for circuits coupled to the Vcc node in the event of an ESD on Vcc node.

An SCR is an intentionally triggered latch-up device which has a high intrinsic turn-on voltage. In this embodiment, inverter-embedded SCR 202 comprises a CMOS based inverter with a p-type device formed in an n-well and an n-type device formed in a p-well. In one embodiment, the parasitic PNPN junction of the inverter is used to form SCR. In such an embodiment, both the inverter and the SCR are formed together such that the SCR is an integral part of the inverter.

One technical effect of inverter-embedded SCR 202 is that a separate SCR and a driving inverter are no longer needed, which results in compact and efficient protection device compared to ESD unit 100. For example, inverter-embedded SCR 202 can provide three times more conductance per unit area compared to conductance per unit area in ESD unit 100. The off-state leakage current for inverter-embedded SCR 202 is considerably less than leakage of MP1 of ESD unit 100. This is because leakage from inverter-embedded SCR 202 comes from reverse-biased junctions, while MP1 of ESD unit 100 suffers from large gate leakage as well as sub-threshold drain-source leakage. The inverter of inverter-embedded SCR 202 is much smaller in size compared to MP1 of ESD unit 100, and so the gate and sub-threshold leakages of the inverter are negligible compared to gate leave of MP1 of ESD 100.

In one embodiment, trigger unit 201 comprises a timer circuit to control when to turn on/off inverter-embedded SCR 202. In one embodiment, timer circuit is an RC timer. In another embodiment, timer circuit is a digital timer with a counter.

FIG. 3 illustrates a circuit 300 of the ESD unit of FIG. 2, according to one embodiment of the disclosure. It is pointed out that those elements of FIG. 3 having the same reference numbers (or names) as the elements of any other figure can operate or function in any manner similar to that described, but are not limited to such.

In one embodiment, circuit 300 comprises trigger unit 301 and inverter (also called first inverter) embedded with an SCR 302. In one embodiment, trigger unit 301 comprises an RC network and second inverter inv2. In one embodiment, resistor R is coupled in series with capacitor C and their common node is received as input for inverter inv2. In one embodiment, output of inverter inv2 coupled to inverter-embedded SCR 302 via node n1.

In one embodiment, inverter-embedded SCR 302 comprises p-type transistor MP, n-type transistor MN, PNP parasitic BJT, and NPN parasitic BJT. Here, R_{PW} and R_{NW} are parasitic resistances of the n-well and p-well (or p-substrate), respectively. In one embodiment, node n2 (i.e., output of inverter-embedded SCR 302) is coupled to the n-well tap (i.e., the base of the PNP BJT). The emitter junction of PNP BJT is coupled to Vcc node while the emitter junction of NPN BJT is coupled to Vss node.

In one embodiment, input to inverter inv2 is low due to uncharged capacitor at the beginning of an unpowered ESD event on Vcc node. The high output of inverter inv2 on node n1 injects current into its parasitic SCR substrate tap and forward biases the base-emitter of the NPN BJT. The low output on node n2 pulls the n-well tap low, which forward biases the base-emitter junction of the PNP BJT. Under normal operating conditions, the n-well and p-well are biased to Vcc and Vss respectively. In such conditions, the triggering voltage is raised and mis-trigger susceptibility is reduced.

In the embodiments, inverter in 302 triggers its own parasitic SCR. In one embodiment, the source terminals of MP and MN are laid out in a way to maximize the coupling between the parasitic PNP and NPN junction devices which together form an intentional SCR embedded in an inverter. The drain terminals of MP and MN are tied together to form an inverter, the output of which (i.e., node n2) is shorted to the N+ tap in the n-well. In one embodiment, when voltage on node n2 is low during an ESD event, n-well is pulled low. This forward biases the base-emitter junction of the PNP and assists to trigger SCR at low voltage.

In one embodiment, output of inverter inv2 is tied to a P+ tap in the substrate to trigger the base-emitter junction of the NPN. During normal operating conditions, output n2 of 302 is high, so the n-well is biased at Vcc. In such an embodiment, minimal DC (direct current) leakage may be observed and the voltage required to trigger the clamp is increased which prevents mis-triggering of the clamp. In the embodiment of inverter-embedded SCR 302, additional parasitic current paths formed by fabricating an intentional SRC embedded with the inverter can further increase the conductance of the clamp.

While the embodiments show two inverters (e.g., inv2 and inverter with embedded SCR), using two inverters is not a requirement. In one embodiment, there can be only the inverter that contains the embedded SCR if the RC stack is flipped. In one embodiment, there could also be three or more inverters coupled together in series, etc.

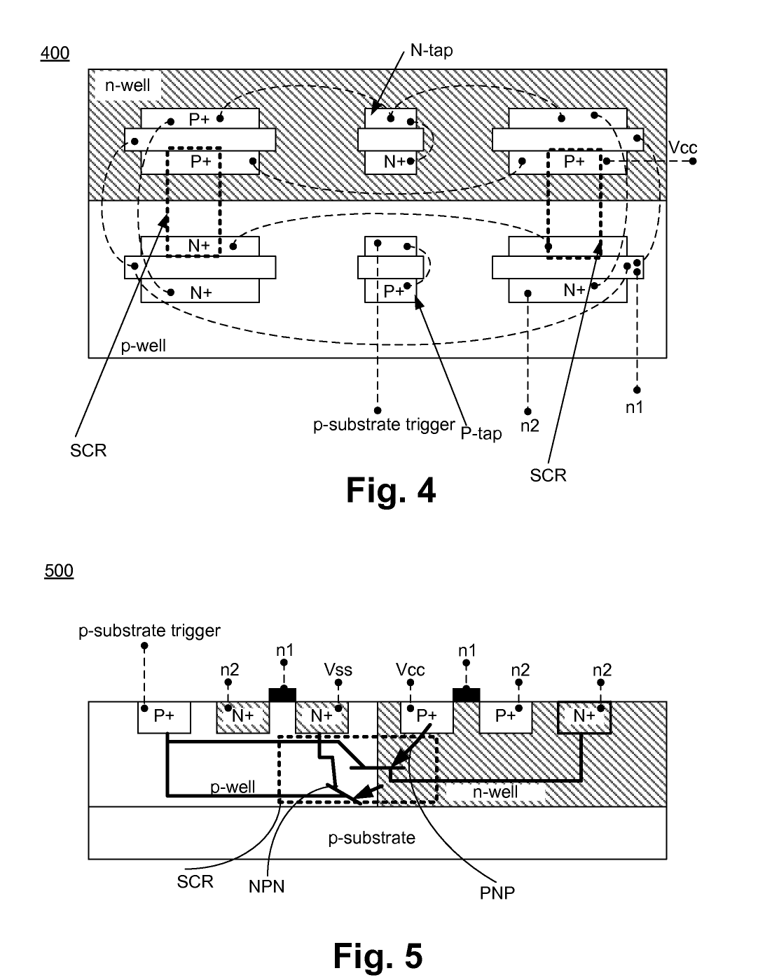

FIG. 4 illustrates a top view 400 of a layout of an inverter-embedded SCR, according to one embodiment of the disclosure. It is pointed out that those elements of FIG. 4 having the same reference numbers (or names) as the elements of any other figure can operate or function in any manner similar to that described, but are not limited to such.

Top view 400 illustrates how an intentional SRC is formed within an inverter. In one embodiment, p-type transistor MP is formed in the n-well and n-type transistor is formed in the p-well. Both n-well and p-well reside in a p-substrate. The curved dashed lines are logical representations of the interconnections formed on higher layers to couple the N-tap, P-tap, MN terminals—gate, source, drain—and MP terminals—gate, source, drain. In this embodiment, the inverter layout is formed in either side of N-tap and P-tap. In other embodiments, the additional inverter layout to the left of N-tap and P-tap regions may be removed. In other embodiments, the N-tap and/or P-tap may be located behind the inverter such that the inverter-SCR lies between the tap and the n-well/p-well junction. It is apparent to one skilled in the art that the sizing, spacing, and location of the various diffusions can be modified to optimize the conductance, trigger and hold voltages, turn-on time, capacitance, and leakage, according to the requirements of the application. The dotted bold rectangle between an MP and MN transistors form the SCR.

Once triggered, the SCR latches on until it is starved of current. In one embodiment, the RC trigger circuit asserts the SCR long enough to turn it on during an ESD event, but need not be long enough to assert the SCR throughout the ESD event given that the SCR will remain latched. In such an embodiment, the RC time constant can be on the order of tens of nanoseconds, making it immune to power ramps slower than hundreds of nanoseconds. In contrast, ESD unit 100 requires that the RC trigger circuit assert for microseconds, making ESD unit 100 susceptible to mis-triggering during ramp rates on the order of 100 ns.

FIG. 5 illustrates a side view 500 of an inverter-embedded SCR, according to one embodiment of the disclosure. It is pointed out that those elements of FIG. 5 having the same reference numbers (or names) as the elements of any other figure can operate or function in any manner similar to that described, but are not limited to such. Side view 500 also shows the parasitic PNP and NPN BJTs formed by the connections of Vcc, Vss, and inverter terminals to generate an SCR embedded in the inverter. The nodes and connections to the wells and diffusion areas (i.e., P+ and N+ diffusion areas) are shown that correspond to connections in FIGS. 3-4.

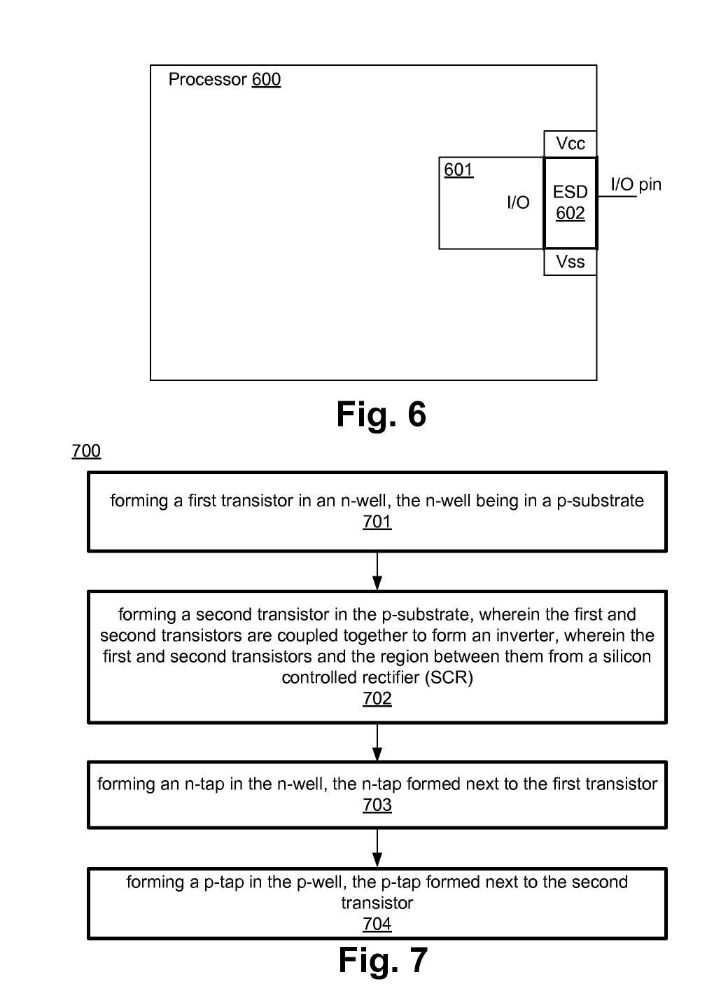

FIG. 6 illustrates a processor 600 with an ESD unit having inverter embedded with an SCR, according to one embodiment of the disclosure. It is pointed out that those elements of FIG. 6 having the same reference numbers (or names) as the elements of any other figure can operate or function in any manner similar to that described, but are not limited to such.

In one embodiment, processor 600 comprises an input-output (I/O) transmitter and/or receiver 601 and ESD unit 602 having an inverter-embedded SCR. An ESD event caused by excessive voltage on the I/O pin can be quickly discharged by ESD unit 602, according to the embodiments. In one embodiment, if an RC timer is used with the inverter-embedded SCR (e.g., 302) as a trigger circuit, the signaling rate of the I/O during normal operating conditions may be made slow enough to prevent the signal from mis-triggering the device. For example, if the RC timer has a time constant of tens of nanoseconds, the signaling rate should be slower than tens of MHz. The embodiments are not limited to an RC timer based triggering circuit. Other types of triggering circuits may be used with the inverter-embedded SCR.

In one embodiment, the inverter-embedded SCR (e.g., 302) is an integral part of a transmitter i.e., the inverter is the transmitting logic which also has built in ESD protection from Vcc to Vss via its embedded SCR.

FIG. 7 illustrates a flowchart 700 of forming an inverter embedded with an SCR, according to one embodiment of the disclosure. It is pointed out that those elements of FIG. 7 having the same reference numbers (or names) as the elements of any other figure can operate or function in any manner similar to that described, but are not limited to such.

Although the blocks in the flowcharts with reference to FIG. 7 are shown in a particular order, the order of the actions can be modified. Thus, the illustrated embodiments can be performed in a different order, and some actions/blocks may be performed in parallel. Some of the blocks and/or operations listed in FIG. 7 are optional in accordance with certain embodiments. The numbering of the blocks presented is for the sake of clarity and is not intended to prescribe an order of operations in which the various blocks must occur. Additionally, operations from the various flows may be utilized in a variety of combinations.

At block 701, a first transistor (e.g., MP of 302) is formed in an n-well, where the n-well resides in a p-substrate. At block 702, a second transistor (e.g., MN of 302) is formed in the p-well which resides in the p-substrate. In one embodiment, the first and second transistors are coupled together to form an inverter. In one embodiment, the regions between the first and second transistors including the source/drain regions of the first and second transistors form an SCR. At block 703, an N-tap is formed in the n-well next to the first transistor. At block 704, a P-tap is formed in the p-well which is next to the second transistor.

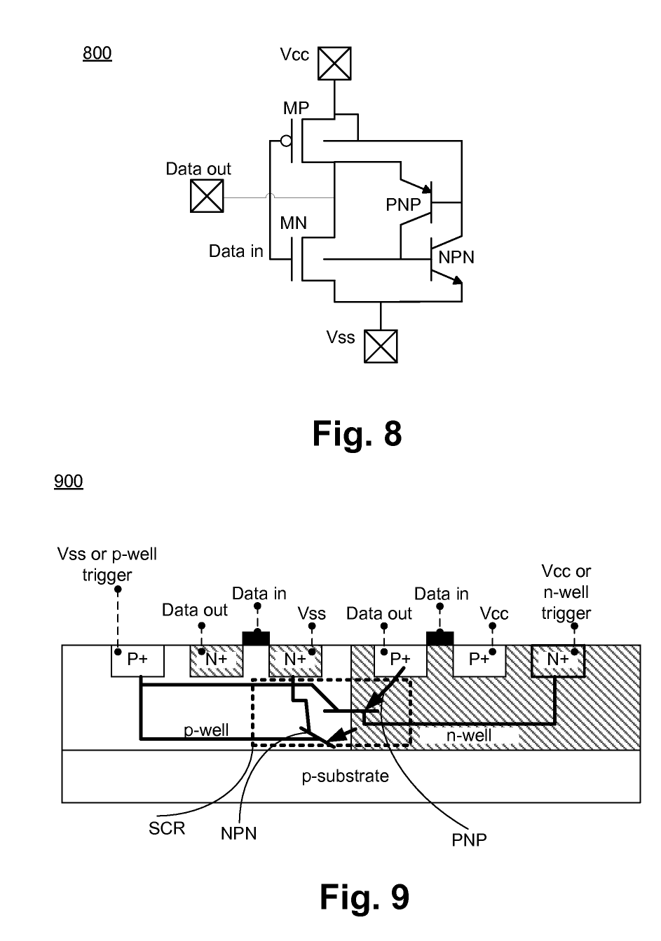

FIG. 8 illustrates an I/O 800 with an inverter-embedded SCR, according to one embodiment of the disclosure. In this embodiment, the embedded SCR provides protection at the I/O pad rather than from Vcc-Vss. It is pointed out that those elements of FIG. 8 having the same reference numbers (or names) as the elements of any other figure can operate or function in any manner similar to that described, but are not limited to such.

In one embodiment, I/O (e.g., transmitter) 800 comprises pad “Data out,” driver having a pull-up device MP and a pull-down device MN, and embedded SCR. In one embodiment, pull-up device MP has a drain terminal coupled to “Data out,” a source terminal coupled to the drain terminal of MN, and a gate terminal coupled to “Data in,” where “Data in” provides the input data for transmission on the pad. In one embodiment, pull-down device MN has a source terminal coupled to ground, a drain terminal coupled to the drain terminal of MP, and a gate terminal coupled to “Data in.”

In this embodiment, an ESD event at “Data out” triggers the SCR and provides ESD protection with respect to Vss. The n-well trigger mechanism is different than the embodiment of FIG. 3. For example, n-well of the embodiment of FIG. 8 is pulled low during an ESD event by either the existing Vcc-Vss clamp or capacitance between Vcc-Vss. A diode trigger string, grounded-gate NMOS, or other trigger circuit could also be used to trigger the n-well. Protection from Vss to “Data out” can be provided either externally (e.g., using a diode from Vss to “Data out”) or by way of the parasitic diode formed between the p-well tap and the NMOS drain N+ diffusion connected to “Data out.”

FIG. 9 illustrates a side view 900 of I/O with the inverter-embedded SCR of FIG. 8, according to one embodiment of the disclosure. It is pointed out that those elements of FIG. 9 having the same reference numbers (or names) as the elements of any other figure can operate or function in any manner similar to that described, but are not limited to such. Side view 900 also shows the parasitic PNP and NPN BJTs formed by the connections of Vcc, Vss, and inverter terminals to generate an SCR embedded in the inverter. The nodes and connections to the wells and diffusion areas (i.e., P+ and N+ diffusion areas) in the side view 900 correspond to connections in FIG. 8.

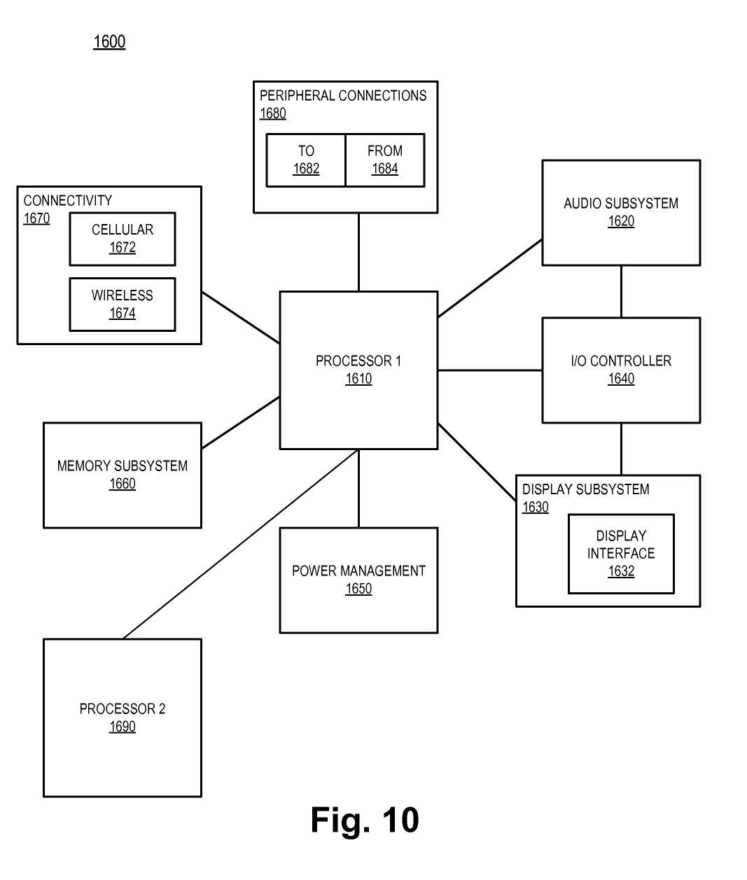

FIG. 10 is a smart device or a computer system or an SoC (System-on-Chip) 1600 with an inverter embedded with an SCR, according to one embodiment of the disclosure. It is pointed out that those elements of FIG. 10 having the same reference numbers (or names) as the elements of any other figure can operate or function in any manner similar to that described, but are not limited to such.

FIG. 10 illustrates a block diagram of an embodiment of a mobile device in which flat surface interface connectors could be used. In one embodiment, computing device 1600 represents a mobile computing device, such as a computing tablet, a mobile phone or smart-phone, a wireless-enabled e-reader, or other wireless mobile device. It will be understood that certain components are shown generally, and not all components of such a device are shown in computing device 1600.

In one embodiment, computing device 1600 includes a first processor 1610 with an inverter embedded with an SCR, according to the embodiments discussed. Other blocks of the computing device 1600 may also include an inverter embedded with an SCR according to the embodiments discussed. The various embodiments of the present disclosure may also comprise a network interface within 1670 such as a wireless interface so that a system embodiment may be incorporated into a wireless device, for example, cell phone or personal digital assistant.

In one embodiment, processor 1610 (and processor 1690) can include one or more physical devices, such as microprocessors, application processors, microcontrollers, programmable logic devices, or other processing means. The processing operations performed by processor 1610 include the execution of an operating platform or operating system on which applications and/or device functions are executed. The processing operations include operations related to I/O (input/output) with a human user or with other devices, operations related to power management, and/or operations related to connecting the computing device 1600 to another device. The processing operations may also include operations related to audio I/O and/or display I/O.

In one embodiment, computing device 1600 includes audio subsystem 1620, which represents hardware (e.g., audio hardware and audio circuits) and software (e.g., drivers, codecs, etc.,) components associated with providing audio functions to the computing device. Audio functions can include speaker and/or headphone output, as well as microphone input. Devices for such functions can be integrated into computing device 1600, or connected to the computing device 1600. In one embodiment, a user interacts with the computing device 1600 by providing audio commands that are received and processed by processor 1610.

Display subsystem 1630 represents hardware (e.g., display devices) and software (e.g., drivers) components that provide a visual and/or tactile display for a user to interact with the computing device 1600. Display subsystem 1630 includes display interface 1632, which includes the particular screen or hardware device used to provide a display to a user. In one embodiment, display interface 1632 includes logic separate from processor 1610 to perform at least some processing related to the display. In one embodiment, display subsystem 1630 includes a touch screen (or touch pad) device that provides both output and input to a user.

I/O controller 1640 represents hardware devices and software components related to interaction with a user. I/O controller 1640 is operable to manage hardware that is part of audio subsystem 1620 and/or display subsystem 1630. Additionally, I/O controller 1640 illustrates a connection point for additional devices that connect to computing device 1600 through which a user might interact with the system. For example, devices that can be attached to the computing device 1600 might include microphone devices, speaker or stereo systems, video systems or other display devices, keyboard or keypad devices, or other I/O devices for use with specific applications such as card readers or other devices.

As mentioned above, I/O controller 1640 can interact with audio subsystem 1620 and/or display subsystem 1630. For example, input through a microphone or other audio device can provide input or commands for one or more applications or functions of the computing device 1600. Additionally, audio output can be provided instead of, or in addition to display output. In another example, if display subsystem 1630 includes a touch screen, the display device also acts as an input device, which can be at least partially managed by I/O controller 1640. There can also be additional buttons or switches on the computing device 1600 to provide I/O functions managed by I/O controller 1640.

In one embodiment, I/O controller 1640 manages devices such as accelerometers, cameras, light sensors or other environmental sensors, or other hardware that can be included in the computing device 1600. The input can be part of direct user interaction, as well as providing environmental input to the system to influence its operations (such as filtering for noise, adjusting displays for brightness detection, applying a flash for a camera, or other features).

In one embodiment, computing device 1600 includes power management 1650 that manages battery power usage, charging of the battery, and features related to power saving operation. Memory subsystem 1660 includes memory devices for storing information in computing device 1600. Memory can include nonvolatile (state does not change if power to the memory device is interrupted) and/or volatile (state is indeterminate if power to the memory device is interrupted) memory devices. Memory subsystem 1660 can store application data, user data, music, photos, documents, or other data, as well as system data (whether long-term or temporary) related to the execution of the applications and functions of the computing device 1600.

Elements of embodiments are also provided as a machine-readable medium (e.g., memory 1660) for storing the computer-executable instructions (e.g., instructions to implement any other processes discussed herein). The machine-readable medium (e.g., memory 1660) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 1670 includes hardware devices (e.g., wireless and/or wired connectors and communication hardware) and software components (e.g., drivers, protocol stacks) to enable the computing device 1600 to communicate with external devices. The computing device 1600 could be separate devices, such as other computing devices, wireless access points or base stations, as well as peripherals such as headsets, printers, or other devices.

Connectivity 1670 can include multiple different types of connectivity. To generalize, the computing device 1600 is illustrated with cellular connectivity 1672 and wireless connectivity 1674. Cellular connectivity 1672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 1674 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 1680 include hardware interfaces and connectors, as well as software components (e.g., drivers, protocol stacks) to make peripheral connections. It will be understood that the computing device 1600 could both be a peripheral device (“to” 1682) to other computing devices, as well as have peripheral devices (“from” 1684) connected to it. The computing device 1600 commonly has a “docking” connector to connect to other computing devices for purposes such as managing (e.g., downloading and/or uploading, changing, synchronizing) content on computing device 1600. Additionally, a docking connector can allow computing device 1600 to connect to certain peripherals that allow the computing device 1600 to control content output, for example, to audiovisual or other systems.

In addition to a proprietary docking connector or other proprietary connection hardware, the computing device 1600 can make peripheral connections 1680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. For example, other memory architectures e.g., Dynamic RAM (DRAM) may use the embodiments discussed. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

For example, in one embodiment, an apparatus is provided which comprises: an inverter; and a silicon controlled rectifier (SCR) embedded in the inverter such that the SCR is part of the inverter. In one embodiment, the apparatus further comprises another inverter having an output coupled to an input of the inverter and the SCR embedded in the inverter. In one embodiment, the apparatus further comprises a timer unit coupled to an input of the other inverter.

In one embodiment, the timer unit is one of: RC timer; or digital timer. In one embodiment, the timer unit to enable the SCR during an electrostatic discharge (ESD) event. In one embodiment, the timer unit to disable the SCR after an electrostatic discharge (ESD) event is over. In one embodiment, the timer unit to disable the SCR under normal operation. In one embodiment, the apparatus further comprises a power supply node and a ground node, wherein the SRC is coupled to the power supply node and the ground node. In one embodiment, the inverter is part of an input-output (I/O) driver. In one embodiment, the inverter is part of an electrostatic discharge (ESD) unit.

In another example, a method is provided which comprises: forming a first transistor in an n-well, the n-well being in a p-substrate; and forming a second transistor in a p-well, the p-well being in the p-substrate, wherein the first and second transistors are coupled together to form an inverter, wherein the first and second transistors and the region between them from a silicon controlled rectifier (SCR). In one embodiment, the method further comprises: forming an n-tap in the n-well, the n-tap formed next to the first transistor; and forming a p-tap in the p-well, the p-tap formed next to the second transistor.

In one embodiment, a system comprises: a memory; a processor coupled to the memory, the processor including an input-output (I/O) transmitter which comprises: an inverter; and a silicon controlled rectifier (SCR) embedded in the inverter such that the SCR is part of the inverter; and a wireless interface for allowing the processor to communicate with another device. In one embodiment, the system further comprises a display unit. In one embodiment, the display unit is a touch screen.

In one embodiment, the I/O transmitter further comprises another inverter having an output coupled to an input of the inverter and the SCR embedded in the inverter. In one embodiment, the I/O transmitter further comprises a timer unit coupled to an input of the other inverter. In one embodiment, the timer unit is one of: RC timer; or digital timer. In one embodiment, the timer unit to: enable the SCR during an electrostatic discharge (ESD) event; disable the SCR after an ESD event is over; and disable the SCR under normal operation.

In another example, a system is provided which comprises: a memory; a processor coupled to the memory, the processor an electrostatic discharge unit according to the apparatus discussed in various embodiments; and a wireless interface for allowing the processor to communicate with another device.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1. An apparatus comprising:
an inverter; and
a silicon controlled rectifier (SCR) embedded in the inverter such that the SCR is part of the inverter.

2. The apparatus of claim 1 further comprises another inverter having an output coupled to an input of the inverter and the SCR embedded in the inverter.

3. The apparatus of claim 2 further comprises a timer unit coupled to an input of the other inverter.

4. The apparatus of claim 3, wherein the timer unit is one of:
RC timer; or
digital timer.

5. The apparatus of claim 4, wherein the timer unit to enable the SCR during an electrostatic discharge (ESD) event.

6. The apparatus of claim 4, wherein the timer unit to disable the SCR after an electrostatic discharge (ESD) event is over.

7. The apparatus of claim 4, wherein the timer unit to disable the SCR under normal operation.

8. The apparatus of claim 1 further comprises a power supply node and a ground node, wherein the SRC is coupled to the power supply node and the ground node.

9. The apparatus of claim 1, wherein the inverter is part of an input-output (I/O) driver.

10. The apparatus of claim 1, wherein the inverter is part of an electrostatic discharge (ESD) unit.

11. A method comprising:
forming a first transistor in an n-well, the n-well being in a p-substrate; and
forming a second transistor in a p-well, the p-well being in the p-substrate, wherein the first and second transistors are coupled together to form an inverter, wherein the first and second transistors and the region between them from a silicon controlled rectifier (SCR).

12. The method of claim 11 further comprises:
forming an n-tap in the n-well, the n-tap formed next to the first transistor; and
forming a p-tap in the p-well, the p-tap formed next to the second transistor.

13. A system comprising:
a memory;
a processor coupled to the memory, the processor including an input-output (I/O) transmitter which comprises:
an inverter; and
a silicon controlled rectifier (SCR) embedded in the inverter such that the SCR is part of the inverter; and
a wireless interface for allowing the processor to communicate with another device.

14. The system of claim 13 further comprises a display unit.

15. The system of claim 14, wherein the display unit is a touch screen.

16. The system of claim 13, wherein the I/O transmitter further comprises another inverter having an output coupled to an input of the inverter and the SCR embedded in the inverter.

17. The system of claim 16, wherein the I/O transmitter further comprises a timer unit coupled to an input of the other inverter.

18. The system of claim 17, wherein the timer unit is one of:
RC timer; or
digital timer.

19. The system of claim 17, wherein the timer unit to:
enable the SCR during an electrostatic discharge (ESD) event;
disable the SCR after an ESD event is over; and
disable the SCR under normal operation.

20. (canceled)

21. The system of claim 13, wherein the inverter is part of an electrostatic discharge (ESD) unit.
